(19) United States
(12) Patent Application Publication
(10) Pub. No.: US 2021/0001601 A1
(43) Pub. Date: Jan. 7, 2021

(54) GAS BARRIER FILM

(71) Applicant: FUJIFILM Corporation, Tokyo (JP)

(72) Inventors: Yoshihiko MOCHIZUKI, Minamiashigara-shi (JP); Shinya SUZUKI, Minamiashigara-shi (JP)

(73) Assignee: FUJIFILM Corporation, Tokyo (JP)

(21) Appl. No.: 17/023,120

(22) Filed: Sep. 16, 2020

Related U.S. Application Data
(63) Continuation of application No. PCT/JP2019/008100, filed on Mar. 1, 2019.

(30) Foreign Application Priority Data
Mar. 28, 2018 (JP) 2018-061802

(51) Int. Cl. B32B 9/00; B32B 7/023

(52) U.S. Cl. CPC B32B 9/005; B32B 7/023; B32B 2250/03; B32B 2264/1021; B32B 2264/12; B32B 2315/02; B32B 2439/46; B32B 2307/7246; B32B 2307/412; B32B 2307/418; B32B 2307/732; B32B 2457/206; B32B 2307/7244

(57) ABSTRACT

A gas barrier film includes a substrate, a base inorganic layer, a silicon nitride layer formed using the base inorganic layer as a base, and a mixed layer formed at a boundary surface of the base inorganic layer and the silicon nitride layer, in which the base inorganic layer contains silicon oxide, the mixed layer contains a component derived from the base inorganic layer and a component derived from the silicon nitride layer, and a thickness of the mixed layer is 3 nm or more.

### CROSS-REFERENCE TO RELATED APPLICATIONS

This application is a Continuation of PCT International Application No. PCT/JP2019/008100 filed on Mar. 1, 2019, which claims priority under 35 U.S.C § 119(a) to Japanese Patent Application No. 2018-061802 filed on Mar. 28, 2018. Each of the above application(s) is hereby expressly incorporated by reference, in its entirety, into the present application.

### BACKGROUND OF THE INVENTION

### 1. Field of the Invention

The present invention relates to a gas barrier film.

### 2. Description of the Related Art

In recent years, high gas barrier performance is required for optical elements (optical devices) such as an organic electroluminescence (EL) element, a solar cell, a quantum dot film, and a display material, packaging materials such as an infusion bag containing a chemical agent which is altered by moisture or oxygen, and the like.

Therefore, necessary gas barrier performance is imparted to these members by sticking a gas barrier film, sealing with the gas barrier film, or the like.

The gas barrier film has, for example, a configuration obtained by forming a gas barrier layer formed of an inorganic material on a substrate.

For example, JP2006-327098A discloses a transparent film in which a transparent gas barrier layer is formed on a first transparent plastic film base material, and a second transparent plastic film base material is disposed on the transparent gas barrier layer through a transparent pressure-sensitive adhesive layer. In addition, JP2006-327098A discloses that the transparent gas barrier layer has a laminated structure in which a silicon nitride layer (SiN layer) is formed on a silicon oxide layer (SiO₂ layer).

### SUMMARY OF THE INVENTION

JP2006-327098A discloses that the SiO₂ layer mainly functions as a gas barrier layer, and the SiN layer functions as a barrier layer against a solvent. Since the SiO₂ layer has a low density, it is necessary to increase the thickness in order to improve barrier performance. However, in a case of increasing the thickness of the SiO₂ layer, there is a problem that the breaking is likely to occur in a case of bending.

In addition, in JP2006-327098A, the SiN layer is formed on the SiO₂ layer by sputtering. However, since the film formation by sputtering has low coverage performance for irregularity on a surface of a substrate, even in a case of forming a very thin (12 nm in Examples) SiN layer on the SiO₂ layer, it is not possible to form a homogeneous coating of the SiO₂ layer. Therefore, the SiN layer formed in this manner does not exhibit sufficient barrier performance.

In addition, in a case of forming the SiN layer on the SiO₂ layer by sputtering, since the adhesive force between the SiN layer and the SiO₂ layer is not high, there is a problem that peeling between the films easily occurs in a case of bending and the like.

An object of the present invention is to solve such problems, and is to provide a gas barrier film having excellent bending resistance.

The object of the present invention is achieved by the following configurations.

[1] A gas barrier film comprising:

a substrate;

a base inorganic layer;

a silicon nitride layer formed using the base inorganic layer as a base; and

a mixed layer formed at a boundary surface of the base inorganic layer and the silicon nitride layer,

in which the base inorganic layer contains silicon oxide,

the mixed layer contains a component derived from the base inorganic layer and a component derived from the silicon nitride layer, and

a thickness of the mixed layer is 3 nm or more.

[2] The gas barrier film according to [1],

in which a ratio t₂/t₁ of a thickness t₂ of the base inorganic layer to a thickness t₁ of the silicon nitride layer is 2 to 50.

[3] The gas barrier film according to [1] or [2],

in which a refractive index of the silicon nitride layer is higher than a refractive index of the base inorganic layer.

[4] The gas barrier film according to any one of [1] to [3],

in which a difference between a refractive index of the silicon nitride layer and a refractive index of the base inorganic layer is 0.2 to 0.5.

[5] The gas barrier film according to any one of [1] to [4],

in which the thickness of the mixed layer is 3 nm to 15 nm.

[6] The gas barrier film according to any one of [1] to [5],

in which a thickness of the base inorganic layer is 5 nm to 800 nm.

[7] The gas barrier film according to any one of [1] to [6],

in which a thickness of the silicon nitride layer is 3 nm to 100 nm.

[8] The gas barrier film according to any one of [1] to [7],

in which a refractive index of the silicon nitride layer is 1.7 to 2.2.

[9] The gas barrier film according to any one of [1] to [8],

in which a refractive index of the base inorganic layer is 1.3 to 1.6.

[10] The gas barrier film according to any one of [1] to [9],

in which two or more combinations of the silicon nitride layer and the base inorganic layer are provided.

According to the present invention, it is possible to provide a gas barrier film having excellent bending resistance.

### BRIEF DESCRIPTION OF THE DRAWINGS

FIG. 1 is a view conceptually showing an example of a gas barrier film according to an embodiment of the present invention.

FIG. 2 is a graph schematically showing a relationship between a position in a thickness direction and composition.

FIG. 3 is a graph showing a relationship between etching time and composition, in which composition of a gas barrier film of Example 1 is measured using XPS spectroscopy.

FIG. 4 is a view conceptually showing another example of the gas barrier film according to the embodiment of the present invention.

FIG. 5 is a view conceptually showing another example of the gas barrier film according to the embodiment of the present invention.

FIG. 6 is a view conceptually showing an example of an inorganic film forming apparatus for producing the gas barrier film according to the embodiment of the present invention.

### DESCRIPTION OF THE PREFERRED EMBODIMENTS

Hereinafter, the gas barrier film according to an embodiment of the present invention will be described with reference to the drawings.

The description of the constitutional requirements described below is made on the basis of representative embodiments of the present invention, but it should not be construed that the present invention is limited to those embodiments. In the drawings of the present specification, the scale of each part is appropriately changed and shown in order to facilitate visual recognition.

In this specification, numerical value ranges expressed by the term “to” mean that the numerical values described before and after “to” are included as a lower limit value and an upper limit value, respectively.

In the following description, “thickness” means a length in a direction (hereinafter, thickness direction) in which a substrate, base inorganic layer, and silicon nitride layer described later are arranged.

[Gas Barrier Film]

The gas barrier film according to the embodiment of the present invention is a gas barrier film including a substrate, a base inorganic layer, a silicon nitride layer formed using the base inorganic layer as a base, and a mixed layer formed at a boundary surface of the base inorganic layer and the silicon nitride layer, in which the base inorganic layer contains silicon oxide, the mixed layer contains a component derived from the base inorganic layer and a component derived from the silicon nitride layer, and a thickness of the mixed layer is 3 nm or more.

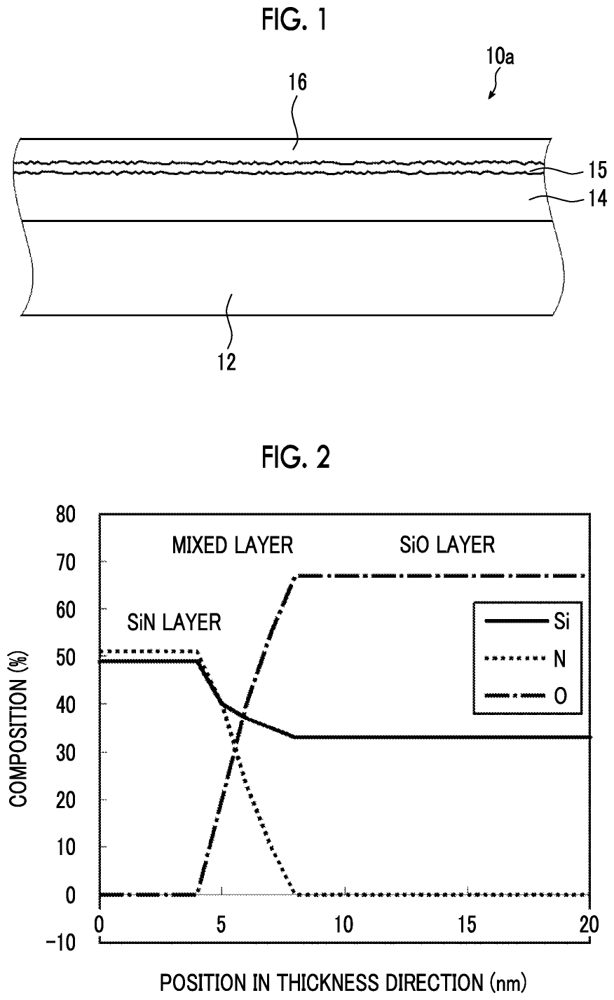

FIG. 1 conceptually shows an example of the gas barrier film according to the embodiment of the present invention.

FIG. 1 is a conceptual view of the gas barrier film according to the embodiment of the present invention viewed from a surface direction of a main surface. The main surface is the largest surface of a sheet-like material (film and plate-like material).

A gas barrier film 10a shown in FIG. 1 is composed of a substrate 12, a base inorganic layer 14, a mixed layer 15, and a silicon nitride layer 16 in this order.

In the following description, in the gas barrier film 10a, a side of the substrate 12 is also referred to as “bottom”, and a side of the silicon nitride layer 16 is also referred to as “top”.

As shown in FIG. 1, the base inorganic layer 14 is placed on a side closer to the substrate 12, and the silicon nitride layer 16 is placed on a side farther from the substrate 12. That is, the base inorganic layer 14 is placed between the silicon nitride layer 16 and the substrate 12. In the example shown in FIG. 1, the base inorganic layer 14 is formed in contact with the substrate 12.

The base inorganic layer 14 is a layer formed of silicon oxide. The base inorganic layer 14 functions as a base layer of the silicon nitride layer 16. Specifically, the base inorganic layer 14 is a layer in which irregularities on the surface of the substrate 12, foreign matters attached to the surface, and the like are embedded so as to form the deposition surface of the silicon nitride layer 16 properly and form a proper silicon nitride layer 16 having no breaking, crack, or the like. In addition, the base inorganic layer 14 acts as a cushion for the silicon nitride layer 16, and can suitably suppress the breaking of the silicon nitride layer 16.

The silicon nitride layer 16 is a layer mainly exhibiting gas barrier performance.

Here, in the gas barrier film 10a according to the embodiment of the present invention, the mixed layer 15 containing a component derived from the base inorganic layer 14 and a component derived from the silicon nitride layer 16 is formed at a boundary surface of the base inorganic layer 14 and the silicon nitride layer 16. The thickness of the mixed layer 15 is 3 nm or more.

As will be described later, in the gas barrier film 10a according to the embodiment of the present invention, the silicon nitride layer 16 is formed on the base inorganic layer 14 according to plasma chemical vapor deposition (CVD). Therefore, in a case of forming the silicon nitride layer 16, by etching the base inorganic layer 14 with plasma, the mixed layer 15 containing a component derived from the base inorganic layer 14 and a component derived from the silicon nitride layer 16 is formed at a boundary surface of the base inorganic layer 14 and the silicon nitride layer 16.

As described above, in a case of a configuration in which a silicon oxide layer (SiO₂ layer) mainly functions as a gas barrier layer, and a silicon nitride layer (SiN layer) functions as a barrier layer against a solvent, since the SiO₂ layer has a low density, it is necessary to increase the thickness in order to improve barrier performance. However, in a case of increasing the thickness of the SiO₂ layer, there is a problem that the breaking is likely to occur in a case of bending.

In addition, in a case where the SiN layer is formed on the SiO₂ layer by sputtering, since the film formation by sputtering has low coverage performance for irregularity on a surface of a substrate, even in a case of forming a very thin SiN layer on the SiO₂ layer, it is not possible to form a homogeneous coating of the SiO₂ layer. Therefore, there is a problem that the SiN layer formed in this manner does not exhibit sufficient barrier performance.

In addition, in a case of forming the SiN layer on the SiO₂ layer by sputtering, since the adhesive force between the SiN layer and the SiO₂ layer is not high, there is a problem that peeling between the films easily occurs in a case of bending and the like.

On the other hand, the gas barrier film 10a according to the embodiment of the present invention has the base inorganic layer 14 formed of silicon oxide, the silicon nitride layer 16 formed using the base inorganic layer 14 as a base, and a mixed layer 15 at the boundary surface of the base inorganic layer 14 and the silicon nitride layer 16, the mixed layer 15 containing a component derived from the base inorganic layer 14 and a component derived from the silicon nitride layer 16 and having a thickness of 3 nm or more.

The gas barrier film 10a according to the embodiment of the present invention has the silicon nitride layer 16 as a layer mainly exhibiting gas barrier performance. Since the silicon nitride layer 16 has a high density, the gas barrier performance can be exhibited even in a case where the thickness is reduced. In a case of reducing the thickness, the silicon nitride layer is less likely to break even in a case of bending, resulting in high bending resistance.

In addition, since the gas barrier film 10a according to the embodiment of the present invention has the mixed layer 15 at the boundary surface of the base inorganic layer 14 and the silicon nitride layer 16, the adhesive force between the base inorganic layer 14 and the silicon nitride layer 16 is high, and peeling between the films hardly occurs in a case of bending and the like, resulting in high bending resistance.

In addition, in the gas barrier film 10a according to the embodiment of the present invention, in order to form the mixed layer 15, the silicon nitride layer 16 is formed on the base inorganic layer 14 according to plasma CVD. Since the silicon nitride layer 16 is formed according to plasma CVD, the silicon nitride layer 16 is formed so as to homogeneously coat the base inorganic layer 14. Therefore, gas barrier performance of the silicon nitride layer 16 is sufficiently exhibited.

From the viewpoint of bending resistance and gas barrier property, the thickness of the mixed layer 15 is preferably 3 nm to 15 nm, more preferably 4 nm to 13 nm, and particularly preferably 5 nm to 10 nm.

Here, it is sufficient that the thickness of the mixed layer 15 (and the thickness of the silicon nitride layer 16) is measured using X-ray photoelectron spectroscopy (XPS). XPS is also called electron spectroscopy for chemical analysis (ESCA).

As an example, in the measurement of the thickness of the mixed layer 15 using XPS, first, etching by argon ion plasma or the like and measurement by XPS are alternately performed to measure the amounts of silicon atoms (Si), nitrogen atoms (N), and oxygen atoms (0) at respective positions in the thickness direction. It is sufficient that the measurement interval in the thickness direction by XPS is appropriately set according to etching rate, measuring device, and the like.

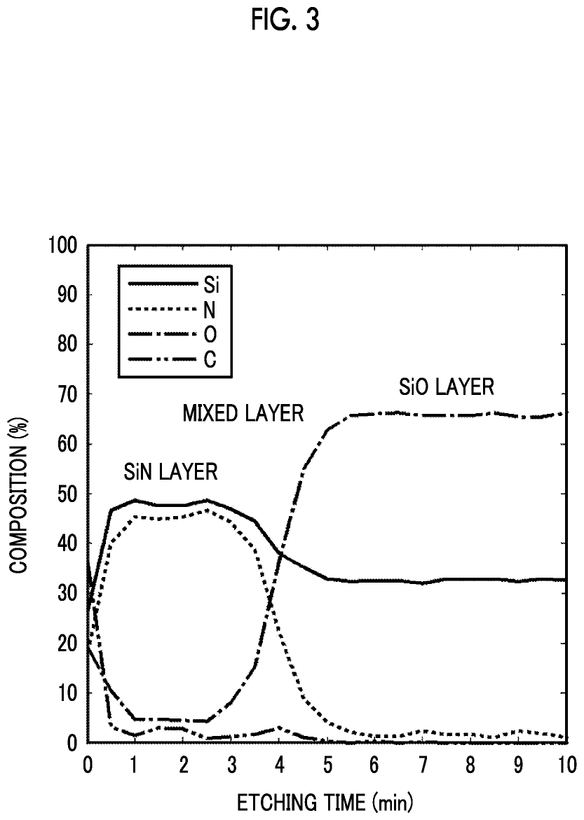

Next, from the etching rate and the etching time, the position in the thickness direction measured by XPS is detected. Furthermore, the total of silicon atoms, nitrogen atoms, and oxygen atoms is set to 1 (that is, 100%), and as the graph schematically shown in FIG. 2, the compositional ratio (compositional ratio profile) of silicon atoms, nitrogen atoms, and oxygen atoms in the thickness direction is detected. In addition, FIG. 3 shows the results of actual measurement of the compositional ratio of silicon atoms, nitrogen atoms, and oxygen atoms in the thickness direction in Example 1 described later.

The measurement by XPS is performed up to a region of the base inorganic layer 14, but in a case where the measurement value by XPS is constant in the region of the base inorganic layer 14, the measurement may not be performed any more.

The example shown in FIG. 2 and FIG. 3 represents the content rate of each atom at each position in the thickness direction (film thickness) with regard to one example, as shown in FIG. 1, of a gas barrier film 10a having a layer structure in which the substrate 12, the base inorganic layer 14, the mixed layer 15, and the silicon nitride layer 16 are laminated in this order. Therefore, the position of 0 nm is the surface of the silicon nitride layer 16. The horizontal axis in FIG. 3 represents the etching time, instead of the position in the thickness direction represented by the horizontal axis in FIG. 2. The etching time and the position in the thickness direction are almost proportional.

Here, the silicon nitride layer 16 does not contain oxygen, but in FIG. 3, oxygen atoms and carbon atoms are detected at a thickness of 0 nm and in the vicinity thereof. This is because, since these elements are mixed into the silicon nitride layer by contamination due to atmospheric components, components inside the device, human fat adhesion during handling, and the like, the mixed components are detected.

Next, the maximum value and the minimum value in the compositional ratio (amount) of nitrogen atoms are detected, and by setting the interval to a range of 100%, the maximum value is set to 100% and the minimum value is set to 0%.

After setting the maximum value in the compositional ratio of nitrogen atoms to 100% and the minimum value in the compositional ratio of nitrogen atoms to 0%, the position in the thickness direction, at which the compositional ratio of nitrogen atoms is reduced by 10% from the maximum value (100%), is defined as a boundary surface of the silicon nitride layer 16 and the mixed layer 15, and the position in the thickness direction, at which the compositional ratio of nitrogen atoms is increased by 10% from the minimum value (0%), is defined as a boundary surface of the mixed layer 15 and the base inorganic layer 14.

In other words, the range from the maximum value (100%) to the minimum value (0%) of the compositional ratio of nitrogen atoms is divided into 10 equal parts, the position in the thickness direction, at which the profile of the compositional ratio of nitrogen atoms and the position (1st part) 1/10 from the top intersect, is defined as the boundary surface of the silicon nitride layer 16 and the mixed layer 15, and the position in the thickness direction, at which the profile of the compositional ratio of nitrogen atoms and the position (9th part) 1/10 from the bottom intersect, is defined as the boundary surface of the mixed layer 15 and the base inorganic layer 14.

In this way, the boundary surface of the silicon nitride layer 16 and the mixed layer 15, and the boundary surface of the mixed layer 15 and the base inorganic layer 14 are determined, and the thickness (from the surface (0 nm) to the boundary surface of the silicon nitride layer 16 and the mixed layer 15) of the silicon nitride layer 16 and the thickness (from the boundary surface of the silicon nitride layer 16 and the mixed layer 15 to the boundary surface of the mixed layer 15 and the base inorganic layer 14) of the mixed layer 15 are detected.

In the gas barrier film 10a according to the embodiment of the present invention, the silicon nitride layer 16 is a layer which mainly exhibits gas barrier performance. Therefore, from the viewpoint of obtaining high gas barrier property, the thickness of the silicon nitride layer 16 is preferably 3 nm or more. In addition, from the viewpoint that it is possible to prevent the breaking of silicon nitride layer (bending resistance), have high transparency, and the like, the thickness of the silicon nitride layer 16 is preferably 100 nm or less. From the viewpoint of gas barrier property, bending resistance, and transparency, the thickness of the silicon nitride layer 16 is more preferably 3 nm to 50 nm and still more preferably 5 nm to 40 nm.

In addition, from the viewpoint that the surface of the base inorganic layer 14 can be flattened by embedding irregularities on the surface of the substrate 12, foreign matters attached to the surface, and the like, a homogeneous silicon nitride layer 16 is easily formed, and the like, the thickness of the base inorganic layer 14 is preferably 5 nm or more. In addition, from the viewpoint that it is possible to prevent cracks (bending resistance), have high transparency, and the like, the thickness of the base inorganic layer 14 is preferably 800 nm or less. From the viewpoint of gas barrier property, bending resistance, and transparency, the thickness of the base inorganic layer 14 is more preferably 10 nm to 600 nm and still more preferably 15 nm to 500 nm.

In addition, from the viewpoint that the base inorganic layer 14 suitably acts as a base layer of the silicon nitride layer 16, bending resistance is increased, transparency is improved, and the like, it is preferable that the base inorganic layer 14 is thicker than the silicon nitride layer 16, and in a case where the thickness of the silicon nitride layer 16 is defined as t₁ and the thickness of the base inorganic layer 14 is defined as t₂, the ratio t₂/t₁ of the thicknesses is preferably 2 to 50, more preferably 2.5 to 35, and still more preferably 3 to 25.

The thicknesses of the silicon nitride layer 16 and the base inorganic layer 14 can be measured by observing a cross section with a transmission electron microscope (TEM).

In addition, from the viewpoint of transparency, it is preferable that the refractive index of the silicon nitride layer 16 is higher than the refractive index of the base inorganic layer 14 (silicon oxide film).

Here, in general, the silicon nitride film has a density higher than that of the silicon oxide film so as to have a higher refractive index. However, the silicon nitride film and the silicon oxide film include other elements such as hydrogen, oxygen, and carbon depending on film forming conditions, such as plasma CVD, in a case of forming a film. By adjusting the contents of these elements, the densities of the silicon nitride film and the silicon oxide film can be respectively adjusted. That is, the density of each of the silicon nitride film and the silicon oxide film can be adjusted by adjusting the film forming conditions. Therefore, the refractive index of the base inorganic layer 14 (silicon oxide film) can be higher than the refractive index of the silicon nitride layer 16.

The contents of the other elements included in the silicon nitride film and the silicon oxide film can be respectively adjusted by adjusting the flow rate of raw material gas in a case of forming a film. In addition, the content of elements in the film can be adjusted by performing a hydrogen plasma treatment, an oxygen plasma treatment, or the like after forming the film.

From the viewpoint of transparency, the difference between the refractive index of the silicon nitride layer 16 and the refractive index of the base inorganic layer 14 is preferably 0.2 or more, more preferably 0.2 to 0.5, and still more preferably 0.25 to 0.4.

In addition, the refractive index of the silicon nitride layer is preferably 1.7 or more and 2.2 or less, more preferably 1.72 or more and 2.1 or less, and still more preferably 1.75 or more and 2.0 or less.

In addition, the refractive index of the base inorganic layer is preferably 1.6 or less, more preferably 1.3 to 1.57, and still more preferably 1.35 to 1.55.

The refractive index is measured using a spectroscopic ellipsometer UVISEL (manufactured by HORIBA, Ltd.). The refractive index is a value of a refractive index at a wavelength of 589.3 nm.

Here, the example shown in FIG. 1 has a configuration in which the silicon nitride layer 16 is laminated on the outermost surface opposite to the substrate 12, but the present invention is not limited to the example.

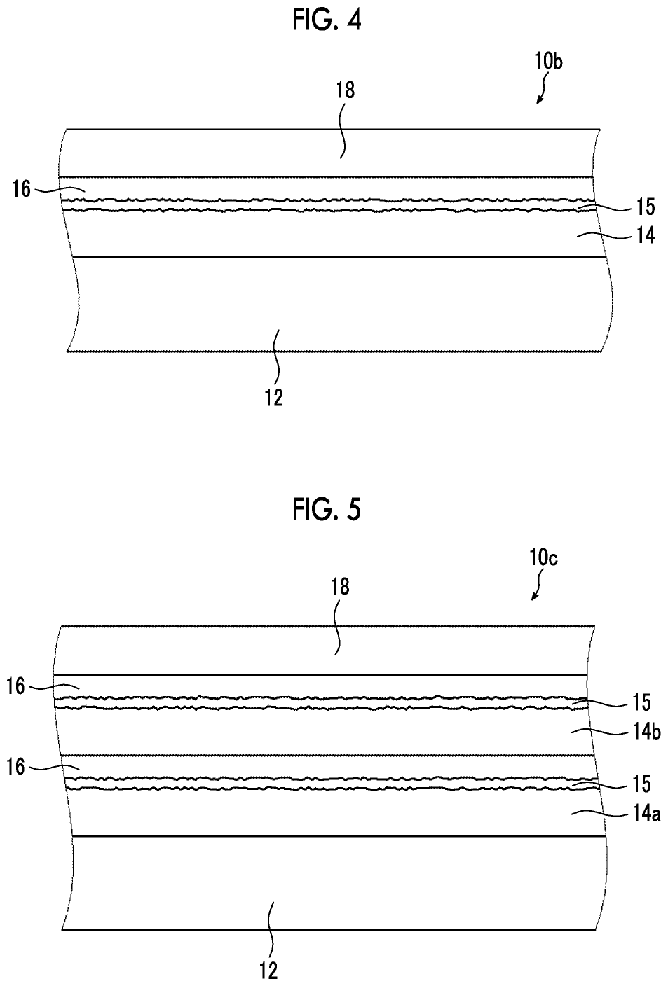

For example, a gas barrier film 10b shown in FIG. 4 has a substrate 12, a base inorganic layer 14, a mixed layer 15, a silicon nitride layer 16, and a protective layer 18 in this order. That is, the gas barrier film 10b has the protective layer 18 on the silicon nitride layer 16, which protects the silicon nitride layer 16.

By having the protective layer 18, the breaking and the like of the silicon nitride layer 16 can be prevented, and bending resistance can be further improved.

The protective layer 18 may be formed of an organic material or may be formed of an inorganic material.

From the viewpoint of transparency, the protective layer 18 is preferably formed of an inorganic material which can be thinned, more preferably formed of an inorganic material having a refractive index lower than that of the silicon nitride layer 16, and still more preferably a silicon oxide film.

In addition, the gas barrier film according to the embodiment of the present invention may have a configuration in which two or more combinations of the base inorganic layer 14 and the silicon nitride layer 16 are included.

For example, a gas barrier film 10c shown in FIG. 5 has a substrate 12, a base inorganic layer 14a, a silicon nitride layer 16, a base inorganic layer 14b, a silicon nitride layer 16, and a protective layer 18 in this order.

The base inorganic layer 14a is a layer which is a base of the silicon nitride layer 16 on a side closer to the substrate 12, the base inorganic layer 14b is a layer which is a base of the silicon nitride layer 16 on a side farther from the substrate 12.

As described above, by having two or more combinations of the silicon nitride layer 16 and the base layer, gas barrier property can be further improved.

Next, each constitutional element of the gas barrier film will be described in detail. In the following description, in a case where it is not necessary to distinguish the gas barrier films 10a to 10c, the gas barrier films 10a to 10c are collectively referred to as the gas barrier film 10. In addition, in a case where it is not necessary to distinguish the base inorganic layer 14a and the base inorganic layer 14b, the base inorganic layer 14a and the base inorganic layer 14b are collectively referred to as the base inorganic layer 14.

<Substrate>

As the substrate 12, a known sheet-like material (film and plate-like material) which is used as a substrate (support) in various gas barrier films, various laminated functional films, and the like can be used.

The material of the substrate 12 is not limited, and various materials can be used as long as the base inorganic layer 14, the silicon nitride layer 16, and the protective layer 18 can be formed. As the material of the substrate 12, various resin materials are preferably exemplified.

Examples of the material of the substrate 12 include polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, polymethyl methacrylate resin (PMMA), polycarbonate (PC), polyacrylate, polymethacrylate, polypropylene (PP), polystyrene (PS), acrylonitrile-butadiene-styrene copolymer (ABS), cycloolefin copolymer (COC), cycloolefin polymer (COP), triacetyl cellulose (TAC), and ethylene-vinyl alcohol copolymer (EVOH).

The thickness of the substrate 12 can be appropriately set depending on the application, the material, and the like.

The thickness of the substrate 12 is not limited, but from the viewpoint that the mechanical strength of the gas barrier film 10 can be sufficiently secured, a gas barrier film having good flexibility can be obtained, the weight and thickness of the gas barrier film 10 can be reduced, a gas barrier film 10 having good flexibility can be obtained, and the like, is preferably 5 to 150 μm and more preferably 10 to 100 μm.

<Silicon Nitride Layer>

The silicon nitride layer 16 is a thin film including silicon nitride as a main component, and formed on the surface of the base inorganic layer 14.

In the gas barrier film 10, the silicon nitride layer 16 mainly exhibits gas barrier performance.

The surface of the substrate 12 may have a region where an inorganic compound is difficult to deposit to form a film, such as irregularities and shadows of foreign matters. As described above, by providing the base inorganic layer 14 on the surface of the substrate 12 and forming the silicon nitride layer 16 thereon, the region where an inorganic compound is difficult to deposit to form a film is covered. Therefore, it is possible to form the silicon nitride layer 16 on the surface of forming the silicon nitride layer 16 (that is, the surface of the base inorganic layer 14) without any gap. In the present specification, the main component refers to a component having the largest content mass ratio among the contained components.

Silicon nitride, which is the material of the silicon nitride layer 16, has high transparency and can exhibit excellent gas barrier performance.

The silicon nitride layer 16 may include elements such as hydrogen and oxygen.

The content of hydrogen in the silicon nitride layer 16 is preferably 10 atom % to 50 atom %, more preferably 15 atom % to 45 atom %, and still more preferably 20 atom % to 40 atom %. As the content of hydrogen is lower, the density of the silicon nitride layer is higher. Therefore, in a case where the content of hydrogen is 10 atom % or more, bending resistance can be improved, and in a case where the content of hydrogen is 50 atom % or less, gas barrier property can be enhanced.

In addition, the silicon nitride layer 16 preferably contains a small amount of oxygen element, and more preferably does not contain oxygen element. The content of oxygen in the silicon nitride layer 16 is preferably 0 atom % to 10 atom %, more preferably 0 atom % to 8 atom %, and still more preferably 0 atom % to 5 atom %. As the content of oxygen is lower, the density of the silicon nitride layer is higher. Therefore, in a case where the content of oxygen is 10 atom % or less, gas barrier property can be enhanced.

Composition of a film (composition of the silicon nitride layer and composition of the base inorganic layer) can be measured according to Rutherford backscattering spectrometry (RBS) measurement using a high-resolution RBS system HRBS-V500 (manufactured by KOBE STEEL, LTD.) and hydrogen forwardscattering spectrometry (HFS) measurement.

As an example shown in FIG. 5, in a case where a plurality of the silicon nitride layers 16 is provided, the thickness of each silicon nitride layer 16 may be the same as or different from each other.

The silicon nitride layer 16 can be formed by a known method depending on the material.

Suitable examples of the method include various vapor deposition methods such as plasma CVD, for example, capacitively coupled plasma (CCP)-CVD, inductively coupled plasma (ICP)-CVD, and the like; atomic layer deposition (ALD); sputtering, for example, magnetron sputtering, reactive sputtering, and the like; and vacuum vapor deposition.

Among these, plasma CVD such as CCP-CVD and ICP-CVD is suitably used from the viewpoint that the mixed layer is formed between the base inorganic layer 14 and the silicon nitride layer 16 to improve the adhesive force. The thickness of the mixed layer can be adjusted by controlling bias power applied to the CCP-CVD film forming electrode. In addition, in a case of a film forming method other than plasma CVD, for example, since plasma-assisted sputtering which generates plasma near the substrate behaves similar to CVD, it is possible to form a mixed layer between the base inorganic layer 14 and the silicon nitride layer 16.

<Base Inorganic Layer>

The base inorganic layer 14 is a layer which is a base of the silicon nitride layer 16, and is a layer in which irregularities on the surface of the substrate 12, foreign matters attached to the surface, and the like are embedded so as to form the deposition surface of the silicon nitride layer 16 properly and form a proper silicon nitride layer 16 having no breaking, crack, or the like. In addition, the base inorganic layer 14 acts as a cushion for the silicon nitride layer 16, and can suitably suppress the breaking of the silicon nitride layer 16.

The base inorganic layer 14 is a layer formed of silicon oxide.

In a case where a plurality of base inorganic layers 14 is provided, that is, a case where a plurality of sets of a combination of the silicon nitride layer 16 and the base inorganic layer 14 is provided, the thickness of each base inorganic layer 14 may be the same as or different from each other.

The silicon oxide film which is the base inorganic layer 14 may include elements such as hydrogen and carbon.

The content of carbon in the silicon oxide film is preferably 2 atom % to 20 atom %, more preferably 3 atom % to 18 atom %, and still more preferably 5 atom % to 15 atom %. As the content of carbon is higher, the density of the silicon oxide film is lower and bending resistance is more improved. On the other hand, as the content of carbon is lower, transparency is improved.

The base inorganic layer 14 can be formed by a known method depending on the material.

In the base inorganic layer 14, suitable examples of the method include various vapor deposition methods such as plasma CVD, for example, capacitively coupled plasma (CCP)-CVD, inductively coupled plasma (ICP)-CVD, and the like; atomic layer deposition (ALD); sputtering, for example, magnetron sputtering, reactive sputtering, and the like; and vacuum vapor deposition. Alternatively, the inorganic base layer may be formed by coating. As the formation by coating, for example, a silicon oxide layer can be formed by coating perhydropolysilazane (PHPS) and reacting perhydropolysilazane with oxygen.

Among these, plasma CVD such as CCP-CVD and ICP-CVD is suitably used from the viewpoint that the adhesive force between the substrate 12 and the base inorganic layer 14 can be improved.

<Protective Layer>

The protective layer 18 is a layer for protecting the silicon nitride layer 16.

The protective layer 18 may be an organic protective layer formed of an organic material, or an inorganic protective layer formed of an inorganic material.

(Organic Protective Layer)

The organic protective layer is, for example, a layer formed of an organic compound obtained by polymerizing (crosslinking and curing) a monomer, a dimer, an oligomer, and the like.

The organic protective layer is formed, for example, by curing a composition for forming an organic protective layer, which contains an organic compound (monomer, dimer, trimer, oligomer, polymer, and the like). The composition for forming an organic protective layer may include one kind of organic compound, or may include two or more kinds thereof.

The organic protective layer contains, for example, a thermoplastic resin, an organosilicon compound, and the like. Examples of the thermoplastic resin include polyester, (meth)acrylic resin, methacrylic acid-maleic acid copolymer, polystyrene, transparent fluororesin, polyimide, fluorinated polyimide, polyamide, polyamideimide, polyetherimide, cellulose acylate, polyurethane, polyetheretherketone, polycarbonate, alicyclic polyolefin, polyarylate, polyethersulfone, polysulfone, fluorene ring-modified polycarbonate, alicyclic-modified polycarbonate, fluorene ring-modified polyester, and acrylic compound. Examples of the organosilicon compound include polysiloxane.

From the viewpoint of excellent strength and viewpoint of glass transition point, the organic protective layer preferably includes a polymerization product of a radically curable compound and/or a cationic curable compound having an ether group.

From the viewpoint of lowering refractive index of the organic protective layer, the organic protective layer preferably includes a (meth)acrylic resin having a polymer of a monomer, oligomer, and the like of (meth)acrylate as a main component. By lowering the refractive index of the organic protective layer, transparency increases and light-transmitting property is improved.

The organic protective layer more preferably includes a (meth)acrylic resin having, as a main component, a polymer of a monomer, dimer, oligomer, and the like of bi- or more functional (meth)acrylate, such as dipropylene glycol di(meth)acrylate (DPGDA), trimethylolpropane tri(meth)acrylate (TMPTA), and dipentaerythritol hexa(meth)acrylate (DPHA), and still more preferably include a (meth)acrylic resin having a polymer of a monomer, dimer, oligomer, and the like of tri- or more functional (meth)acrylate as a main component. In addition, a plurality of these (meth)acrylic resins may be used.

The composition for forming an organic protective layer preferably includes an organic solvent, a surfactant, a silane coupling agent, and the like, in addition to the organic compound.

The thickness of the organic protective layer is not limited, and can be appropriately set depending on the components included in the composition for forming an organic protective layer, the substrate 12 to be used, and the like.

The thickness of the organic protective layer is preferably 80 nm to 1000 nm. By setting the thickness of the organic protective layer to 80 nm or more, the silicon nitride layer 16 can be sufficiently protected. In addition, from the viewpoint that the breaking can be prevented and a decrease in transmittance can be prevented, the thickness of the organic protective layer is preferably 1000 nm or less. Furthermore, the thickness of the organic protective layer is more preferably 80 nm to 500 nm and still more preferably 100 nm to 400 nm.

The organic protective layer can be formed by a known method depending on the material.

For example, the organic protective layer can be formed according to a coating method in which the above-described composition for forming an organic protective layer is applied and dried. In the formation of the organic protective layer according to the coating method, the dried composition for forming an organic protective layer is further irradiated with ultraviolet rays to polymerize (crosslink) the organic compound in the composition as necessary.

(Inorganic Protective Layer)

The inorganic protective layer is a layer formed of an inorganic material. The inorganic protective layer is preferably formed of an inorganic material having a refractive index lower than that of the silicon nitride layer 16.

As the inorganic protective layer, various films which have a refractive index lower than that of the silicon nitride layer 16, have high transparency, and are formed of a material having good adhesiveness to the substrate 12 and the silicon nitride layer 16 can be used. For example, a silicon oxide film, an aluminum oxide film, or the like can be used.

In particular, from the viewpoint that the inorganic protective layer has high transparency and has flexibility, and various materials and film forming methods can be used, a silicon oxide film is suitably exemplified.

The thickness of the inorganic protective layer can be appropriately set depending on the material of the inorganic protective layer, and the like.

The thickness of the inorganic protective layer is preferably 10 nm to 1000 nm, more preferably 20 nm to 800 nm, and still more preferably 30 nm to 600 nm.

The aspect in which the thickness of the inorganic protective layer is 10 nm or more is preferable from the viewpoint that the silicon nitride layer can be protected, transparency can be increased by suppressing surface reflection, and the like. The aspect in which the thickness of the inorganic protective layer is 1000 nm or less is preferable from the viewpoint that transparency can be increased, cracks in the inorganic protective layer can be prevented, flexibility of the gas barrier film can be increased, and the like.

The inorganic protective layer can be formed by a known method depending on the material.

Suitable examples of the method include various vapor deposition methods such as plasma CVD, for example, capacitively coupled plasma (CCP)-CVD, inductively coupled plasma (ICP)-CVD, and the like; atomic layer deposition (ALD); sputtering, for example, magnetron sputtering, reactive sputtering, and the like; and vacuum vapor deposition. Alternatively, the inorganic base layer may be formed by coating. As the formation by coating, for example, a silicon oxide layer can be formed by coating perhydropolysilazane (PHPS) and reacting perhydropolysilazane with oxygen.

Among these, plasma CVD such as CCP-CVD and ICP-CVD is suitably used from the viewpoint that the adhesive force between the silicon nitride layer 16 and the inorganic protective layer can be improved.

[Method for Producing Gas Barrier Film]

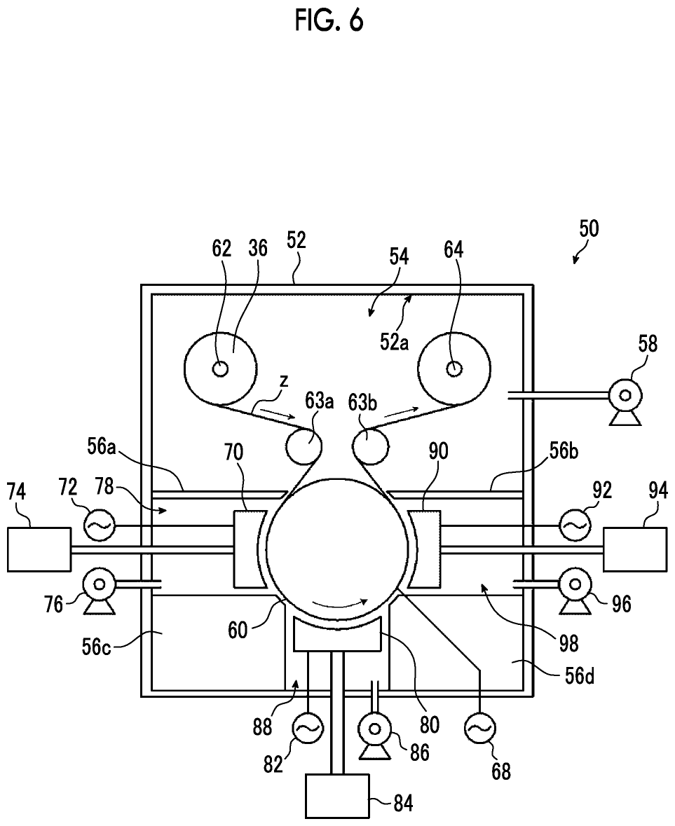

Hereinafter, an example of a method for producing the gas barrier film 10 according to the embodiment of the present invention will be described with reference to the conceptual view of FIG. 6.

An apparatus shown in FIG. 6 is basically a known roll-to-roll film forming apparatus according to plasma CVD. Hereinafter, using the apparatus shown in FIG. 6, a case of producing the gas barrier film 10b as shown in FIG. 4, which has a protective layer 18 and in which the protective layer 18 is an inorganic protective layer 18, will be described.

A film forming apparatus 50 shown in FIG. 6 is an apparatus for producing a gas barrier film by, while transporting the substrate 12, which is an object Z to be treated, in a longitudinal direction, sequentially forming the base inorganic layer 14, the silicon nitride layer 16, and the inorganic protective layer 18 on a surface of the object Z to be treated according to plasma CVD.

In addition, the film forming apparatus 50 is an apparatus for forming a film by so-called roll-to-roll (hereinafter, also referred to as RtoR), in which an object Z to be treated is sent out from a laminate roll 36 formed by winding a long object Z (substrate 12) to be treated in a roll shape, the base inorganic layer 14, the silicon nitride layer 16, and the inorganic protective layer 18 are formed while transporting the object Z to be treated in a longitudinal direction, and the produced gas barrier film is wound in a roll shape.

The film forming apparatus 50 shown in FIG. 6 is an apparatus capable of forming a film on the object Z to be treated according to capacitively coupled plasma (CCP)-CVD, and is composed of a vacuum chamber 52, and an unwinding section 54, three film forming sections (first film forming section 78, second film forming section 88, and third film forming section 98), and a drum 60, which are formed in the vacuum chamber 52.

That is, the film forming apparatus 50 is an apparatus which has three film forming sections in the transport path of the object Z to be treated, and in which the base inorganic layer 14, the silicon nitride layer 16, and the inorganic protective layer 18 are respectively formed in the three film forming sections.

In the film forming apparatus 50, the long object Z to be treated is supplied from the laminate roll 36 of the unwinding section 54. Next, while transporting the long object Z to be treated, which is in a state of being wound around the drum 60, in the longitudinal direction, the base inorganic layer 14 is formed on the long object Z to be treated in the film forming section 78, the silicon nitride layer 16 is formed on the long object Z to be treated in the film forming section 88, and the inorganic protective layer 18 is formed on the long object Z to be treated in the film forming section 98. Thereafter, the long object Z to be treated is transported to the unwinding section 54 again, and wound up on a winding shaft 64 in the unwinding section 54.

The drum 60 is a cylindrical member, and rotates counterclockwise around an axis, as a rotating shaft, passing through the center of the circle and perpendicular to the drawing sheet. The drum 60 winds the object Z to be treated, which is guided by a guide roller 63a of the unwinding section 54 described later in a predetermined path, around a predetermined region of a peripheral surface, transports the object Z to be treated in the longitudinal direction while holding the object Z to be treated at a predetermined position, sequentially transports the object Z to be treated to the film forming section 78, the film forming section 88, and the film forming section 98, and sends the object Z to be treated to a guide roller 63b of the unwinding section 54.

Here, the drum 60 also acts as a counter electrode of film forming electrodes of respective film forming sections described later. That is, the drum 60 and each film forming electrode form an electrode pair.

In addition, a bias power supply 68 is connected to the drum 60.

The bias power supply 68 is a power supply which supplies bias power to the drum 60.

The bias power supply 68 is basically a known bias power supply used in various plasma CVD apparatuses.

The unwinding section 54 is composed of an inner wall surface 52a of the vacuum chamber 52, a peripheral surface of the drum 60, and partition walls 56a and 56b extending from the inner wall surface 52a to the vicinity of the peripheral surface of the drum 60.

The unwinding section 54 has the above-described winding shaft 64, guide rollers 63a and 63b, a rotating shaft 62, and a vacuum exhaust unit 58.

The guide rollers 63a and 63b are normal guide rollers which guide the object Z to be treated along a predetermined transport path. In addition, the winding shaft 64 is a known long winding shaft which winds up the film-formed object Z to be treated.

In the illustrated example, the laminate roll 36, which is formed by winding the long object Z to be treated in a roll shape, is mounted in the rotating shaft 62. In addition, in a case where the laminate roll 36 is mounted in the rotating shaft 62, the object Z to be treated is passed through a predetermined path, through the guide roller 63a, drum 60, and guide roller 63b, thereby reaching the winding shaft 64.

The vacuum exhaust unit 58 is a vacuum pump for reducing the pressure in the unwinding section 54 to a predetermined degree of vacuum. The vacuum exhaust unit 58 sets the pressure in the unwinding section 54 to a pressure which does not affect the pressure in the film forming section 78, the film forming section 88, and the film forming section 98.

In the transport direction of the object Z to be treated, the film forming section 78 is disposed downstream of the unwinding section 54.

The film forming section 78 is composed of the inner wall surface 52a, the peripheral surface of the drum 60, and partition walls 56a and 56c extending from the inner wall surface 52a to the vicinity of the peripheral surface of the drum 60.

In the film forming apparatus 50, a film of the base inorganic layer 14 is formed on the surface of the object Z to be treated according to capacitively coupled plasma (CCP)-CVD in the film forming section 78. The film forming section 78 has a film forming electrode 70, a raw material gas supply unit 74, and a high-frequency power supply 72, and a vacuum exhaust unit 76.

The film forming electrode 70 is an electrode which constitutes, in the film forming apparatus 50, an electrode pair together with the drum 60 in a case of forming a film according to CCP-CVD. The film forming electrode 70 is disposed such that an electric discharge surface, which is one largest surface, faces the peripheral surface of the drum 60. The film forming electrode 70 generates plasma for forming a film between the electric discharge surface and the peripheral surface of the drum 60 forming the electrode pair, thereby forming a film forming region.

In addition, the film forming electrode 70 may be a so-called shower electrode in which a large number of through holes are entirely formed on the electric discharge surface.

The raw material gas supply unit 74 is a known gas supply unit used in a vacuum film forming apparatus such as a plasma CVD apparatus, and supplies a raw material gas into the film forming electrode 70. It is sufficient that the raw material gas supplied by the raw material gas supply unit 74 is appropriately selected according to the forming material of the base inorganic layer 14 to be formed.

The high-frequency power supply 72 is a power supply which supplies plasma excitation power to the film forming electrode 70. As the high-frequency power supply 72, all known high-frequency power supplies used in various plasma CVD apparatuses can also be used.

Furthermore, the vacuum exhaust unit 76 is a known vacuum exhaust unit which is used in a vacuum film forming apparatus and in which the inside of the film forming section 78 is exhausted to maintain a predetermined film forming pressure in order to form the base inorganic layer 14 according to plasma CVD.

As described above, it is sufficient that the method for forming the base inorganic layer 14 is performed, depending on the base inorganic layer 14 to be formed, according to a known vapor deposition method such as plasma CVD, for example, CCP-CVD, ICP-CVD, and the like; sputtering, for example, magnetron sputtering, reactive sputtering, and the like; and vacuum vapor deposition. Among these, as described above, plasma CVD such as CCP-CVD is suitably used in the formation of the base inorganic layer 14. Therefore, it is sufficient that the process gas to be used, the film forming conditions, and the like is appropriately set and selected depending on the material and film thickness of the base inorganic layer 14 to be formed, and the like.

The object Z to be treated, in which the base inorganic layer 14 is formed on the surface of the substrate 12 in the film forming section 78, is transported to the film forming section 88 disposed downstream of the film forming section 78.

The film forming section 88 is composed of the inner wall surface 52a, the peripheral surface of the drum 60, and partition walls 56c and 56d extending from the inner wall surface 52a to the vicinity of the peripheral surface of the drum 60.

In the film forming apparatus 50, a film of the silicon nitride layer 16 is formed on the surface of the object Z to be treated, that is, on the base inorganic layer 14 according to capacitively coupled plasma (CCP)-CVD in the film forming section 88. The film forming section 88 has a film forming electrode 80, a raw material gas supply unit 84, and a high-frequency power supply 82, and a vacuum exhaust unit 86.

The film forming electrode 80, the raw material gas supply unit 84, the high-frequency power supply 82, and the vacuum exhaust unit 86 are respectively the same as the film forming electrode 70, the raw material gas supply unit 74, the high-frequency power supply 72, and the vacuum exhaust unit 76 in the film forming section 78.

As described above, it is sufficient that the method for forming the silicon nitride layer 16 is performed, depending on the silicon nitride layer 16 to be formed, according to a known vapor deposition method such as plasma CVD, for example, CCP-CVD, ICP-CVD, and the like. Among these, as described above, plasma CVD such as CCP-CVD is suitably used in the formation of the silicon nitride layer 16. Therefore, it is sufficient that the process gas to be used, the film forming conditions, and the like is appropriately set and selected depending on the material and film thickness of the silicon nitride layer 16 to be formed, and the like.

The object Z to be treated, in which the silicon nitride layer 16 is formed on the base inorganic layer 14 in the film forming section 88, is transported to the film forming section 98 disposed downstream of the film forming section 88.

The film forming section 98 is composed of the inner wall surface 52a, the peripheral surface of the drum 60, and partition walls 56d and 56b extending from the inner wall surface 52a to the vicinity of the peripheral surface of the drum 60.

In the film forming apparatus 50, a film of the inorganic protective layer 18 is formed on the surface of the object Z to be treated, that is, on the silicon nitride layer 16 according to capacitively coupled plasma (CCP)-CVD in the film forming section 98. The film forming section 98 has a film forming electrode 90, a raw material gas supply unit 94, and a high-frequency power supply 92, and a vacuum exhaust unit 96.

The film forming electrode 90, the raw material gas supply unit 94, the high-frequency power supply 92, and the vacuum exhaust unit 96 are respectively the same as the film forming electrode 70, the raw material gas supply unit 74, the high-frequency power supply 72, and the vacuum exhaust unit 76 in the film forming section 78.

As described above, it is sufficient that the method for forming the inorganic protective layer 18 is performed, depending on the inorganic protective layer 18 to be formed, according to a known vapor deposition method such as plasma CVD, for example, CCP-CVD, ICP-CVD, and the like; sputtering, for example, magnetron sputtering, reactive sputtering, and the like; and vacuum vapor deposition. Among these, as described above, plasma CVD such as CCP-CVD is suitably used in the formation of the inorganic protective layer 18. Therefore, it is sufficient that the process gas to be used, the film forming conditions, and the like is appropriately set and selected depending on the material and film thickness of the inorganic protective layer 18 to be formed, and the like.

The object Z to be treated in which the inorganic protective layer 18 is formed in the film forming section 98, that is, the gas barrier film 10 according to the embodiment of the present invention is transported into the unwinding section 54, guided by the guide roller 63b along a predetermined path, reaches the winding shaft 64, and wound around the winding shaft 64.

In the above-described method for producing a gas barrier film, all the layers are formed by roll-to-roll (RtoR) in one film forming apparatus as a preferred aspect, but the method may include an aspect in which at least one step is performed by another film forming apparatus. In addition, the method may include an aspect in which at least one step may be performed batchwise, or all the steps may be performed batchwise with cut sheets.

In addition, as the example shown in FIG. 5, in a case where two or more combinations of the base inorganic layer 14 and the silicon nitride layer 16 are included, a film forming apparatus having film forming sections corresponding to the number of layers to be formed may be used, or at least one step may be performed by another film forming apparatus.

In addition, in the above-described method for producing a gas barrier film, the case where the protective layer 18 is an inorganic protective layer has been described. However, in a case where the protective layer 18 is an organic protective layer, it is sufficient that the base inorganic layer 14 and the silicon nitride layer 16 are formed on the surface of the substrate 12, the wound object Z to be treated is moved to a film forming apparatus for forming an organic layer, and the organic protective layer is formed on the silicon nitride layer 16.

Here, in a case where the film formation is performed by a plurality of apparatuses, such as a case where the protective layer 18 is an organic protective layer, a step of, in a case of moving the object Z to be treated to another apparatus, adhering a protective film to protect the formed layer and peeling off the protective film in a case of forming next layer is necessary.

On the other hand, in a case where the protective layer 18 is an inorganic protective layer, all layers can be formed in one film forming apparatus. Therefore, the step of adhering and peeling off the protective film is not necessary, which is suitable from the viewpoint of simplification of steps, no pressure sensitive adhesive residue of the protective film, and cost.

Hereinbefore, the gas barrier film according to the embodiment of the present invention has been described in detail, but the present invention is not limited to the above-described aspects and various improvements and changes can be made without departing from the spirit of the present invention.

For example, in the above-described method for producing a gas barrier film, all the layers are formed by RtoR as a preferred aspect, but at least one step may be performed batchwise after cutting the film, or all the steps may be performed batchwise with cut sheets.

### EXAMPLES

Hereinafter, the present invention will be described in more detail with reference to Examples. The present invention is not limited to the following specific examples.

### Example 1

As a substrate, a PET film manufactured by TOYOBO Co., Ltd., COSMOSHINE A4100; refractive index: 1.54) having a thickness of 100 μm and a width of 1000 mm was prepared. A base inorganic layer and a silicon nitride layer were formed on a surface of the substrate on a side not having an easily adhesive layer as follows.

<Formation of Base Inorganic Layer and Silicon Nitride Layer>

Using an apparatus, as shown in FIG. 6, having three film forming sections for forming a film according to CCP-CVD by RtoR, the PET film (substrate) was used as an object Z to be treated, and the object Z to be treated was subjected to the following base inorganic layer forming step and silicon nitride layer forming step to form a base inorganic layer and a silicon nitride layer, thereby producing a gas barrier film.

In Examples 1 to 15, the base inorganic layer and the silicon nitride layer were formed using two of the three film forming sections.

The transport speed of the object Z to be treated was set to 2 m/min.

A bias power of 1 kW at a frequency of 0.1 MHz and was applied to a drum.

(Base Inorganic Layer Forming Step)

As a raw material gas for forming the base inorganic layer, hexamethyldisiloxane (HMDSO) gas represented by the following structural formula, and oxygen gas (O₂) were used. The gas supply amount was 400 sccm for HMDSO and 600 sccm for oxygen gas. In addition, the film forming pressure was set to 100 Pa. The plasma excitation power was set to 4 kW at a frequency of 13.56 MHz. That is, the base inorganic layer is a silicon oxide film.

The flow rate expressed in unit of sccm is a value converted into a flow rate (cc/min) at 1013 hPa and 0° C.

The thickness of the formed base inorganic layer was 80 nm.

In addition, the refractive index of the base inorganic layer was 1.48.

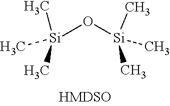

(Silicon Nitride Layer Forming Step)

As a raw material gas for forming the silicon nitride layer, silane gas (SiH₄), ammonia gas (NH₃), and hydrogen gas (H₂) were used. The gas supply amount was 200 sccm for silane gas, 600 sccm for ammonia gas, and 1000 sccm for hydrogen gas. In addition, the film forming pressure was set to 100 Pa. The plasma excitation power was set to 1.5 kW at a frequency of 13.56 MHz.

The thickness of the formed silicon nitride layer was 10 nm.

In addition, the refractive index of the silicon nitride layer was 1.8.

Therefore, the ratio t₂/t₁ of the thickness t₂ of the base inorganic layer to the thickness t₁ of the silicon nitride layer was 8.0. In addition, the difference in refractive index between the silicon nitride layer and the base inorganic layer was 0.32.

In addition, to the produced gas barrier film, etching by argon ion plasma and measurement by XPS are alternately performed from the silicon nitride layer side to measure the amounts of silicon atoms (Si), nitrogen atoms (N), and oxygen atoms (0) at respective positions in a thickness direction, and a compositional ratio profile was obtained.

From the obtained compositional ratio profile, the maximum value and the minimum value in the compositional ratio (amount) of nitrogen atoms were detected, and by setting the interval to a range of 100%, the maximum value was set to 100% and the minimum value was set to 0%. Thereafter, the position in the thickness direction, at which the compositional ratio of nitrogen atoms is reduced by 10% from the maximum value (100%), was defined as a boundary surface of the silicon nitride layer and a mixed layer, and the position in the thickness direction, at which the compositional ratio of nitrogen atoms was increased by 10% from the minimum value (0%), was defined as a boundary surface of the mixed layer and the base inorganic layer, thereby obtaining the thickness of the mixed layer. The thickness of the mixed layer was 5.3 nm.

### Example 2

A gas barrier film was produced in the same manner as in Example 1, except that, in the silicon nitride layer forming step, the supply amount of silane gas was set to 100 sccm, the supply amount of ammonia gas was set to 300 sccm, the supply amount of hydrogen gas was set to 1000 sccm, and the plasma excitation power was set to 0.8 kW.

The thickness of the formed silicon nitride layer was 5 nm. Therefore, the ratio t₂/t₁ of the thickness t₂ of the base inorganic layer to the thickness t₁ of the silicon nitride layer was 16.

In addition, the thickness of the mixed layer was 4.5 nm.

### Example 3

A gas barrier film was produced in the same manner as in Example 2, except that the transport speed of the object Z to be treated in a case of forming the base inorganic layer and the silicon nitride layer was set to 1 m/min.

The thickness of the formed base inorganic layer was 170 nm. In addition, the thickness of the formed silicon nitride layer was 10 nm. Therefore, the ratio t₂/t₁ of the thickness t₂ of the base inorganic layer to the thickness t₁ of the silicon nitride layer was 17.0.

In addition, the thickness of the mixed layer was 4.7 nm.

### Example 4

A gas barrier film was produced in the same manner as in Example 1, except that the bias power applied to the drum was set to 0.5 kW.

The thickness of the formed base inorganic layer was 80 nm. In addition, the thickness of the formed silicon nitride layer was 12 nm. Therefore, the ratio t₂/t₁ of the thickness t₂ of the base inorganic layer to the thickness t₁ of the silicon nitride layer was 6.67.

In addition, the thickness of the mixed layer was 3.2 nm.

### Example 5

A gas barrier film was produced in the same manner as in Example 3, except that, in the base inorganic layer forming step, the supply amount of HMDSO was set to 600 sccm, the supply amount of oxygen gas was set to 900 sccm, and the plasma excitation power was set to 5.5 kW.

The thickness of the formed base inorganic layer was 240 nm. In addition, the thickness of the formed silicon nitride layer was 10 nm. Therefore, the ratio t₂/t₁ of the thickness t₂ of the base inorganic layer to the thickness t₁ of the silicon nitride layer was 24.0.

In addition, the thickness of the mixed layer was 5.0 nm.

### Example 6

A gas barrier film was produced in the same manner as in Example 3, except that, in the base inorganic layer forming step, the supply amount of HMDSO was set to 1000 sccm, the supply amount of oxygen gas was set to 1500 sccm, and the plasma excitation power was set to 8 kW.

The thickness of the formed base inorganic layer was 450 nm. In addition, the thickness of the formed silicon nitride layer was 10 nm. Therefore, the ratio t₂/t₁ of the thickness t₂ of the base inorganic layer to the thickness t₁ of the silicon nitride layer was 45.0.

In addition, the thickness of the mixed layer was 5.1 nm.

### Example 7

A gas barrier film was produced in the same manner as in Example 3, except that, in the base inorganic layer forming step, the supply amount of HMDSO was set to 1200 sccm, the supply amount of oxygen gas was set to 1800 sccm, and the plasma excitation power was set to 10 kW.

The thickness of the formed base inorganic layer was 570 nm. In addition, the thickness of the formed silicon nitride layer was 10 nm. Therefore, the ratio t₂/t₁ of the thickness t₂ of the base inorganic layer to the thickness t₁ of the silicon nitride layer was 57.0.

In addition, the thickness of the mixed layer was 5.1 nm.

### Example 8

A gas barrier film was produced in the same manner as in Example 1, except that, in the base inorganic layer forming step, the supply amount of HMDSO was set to 150 sccm, the supply amount of oxygen gas was set to 375 sccm, and the plasma excitation power was set to 2 kW.

The thickness of the formed base inorganic layer was 32 nm. In addition, the thickness of the formed silicon nitride layer was 10 nm. Therefore, the ratio t₂/t₁ of the thickness t₂ of the base inorganic layer to the thickness t₁ of the silicon nitride layer was 3.2.

In addition, the thickness of the mixed layer was 5.3 nm.

### Example 9

A gas barrier film was produced in the same manner as in Example 1, except that, in the base inorganic layer forming step, the supply amount of HMDSO was set to 60 sccm, the supply amount of oxygen gas was set to 90 sccm, and the plasma excitation power was set to 0.5 kW.

The thickness of the formed base inorganic layer was 15 nm. In addition, the thickness of the formed silicon nitride layer was 10 nm. Therefore, the ratio t₂/t₁ of the thickness t₂ of the base inorganic layer to the thickness t₁ of the silicon nitride layer was 1.5.

In addition, the thickness of the mixed layer was 5.3 nm.

### Example 10

A gas barrier film was produced in the same manner as in Example 1, except that the transport speed of the object Z to be treated in a case of forming the base inorganic layer and the silicon nitride layer was set to 0.5 m/min, and in the silicon nitride layer forming step, the supply amount of silane gas was set to 400 sccm, the supply amount of ammonia gas was set to 1200 sccm, the supply amount of hydrogen gas was set to 2000 sccm, and the plasma excitation power was set to 3.5 kW.

The thickness of the formed base inorganic layer was 350 nm. In addition, the thickness of the formed silicon nitride layer was 92 nm. Therefore, the ratio t₂/t₁ of the thickness t₂ of the base inorganic layer to the thickness t₁ of the silicon nitride layer was 3.8.

In addition, the thickness of the mixed layer was 6.2 nm.

### Example 11

A gas barrier film was produced in the same manner as in Example 10, except that, in the silicon nitride layer forming step, the supply amount of silane gas was set to 500 sccm, the supply amount of ammonia gas was set to 1500 sccm, the supply amount of hydrogen gas was set to 2000 sccm, and the plasma excitation power was set to 4.5 kW.

The thickness of the formed silicon nitride layer was 106 nm. Therefore, the ratio t₂/t₁ of the thickness t₂ of the base inorganic layer to the thickness t₁ of the silicon nitride layer was 3.3.

In addition, the thickness of the mixed layer was 6.4 nm.

### Example 12

A gas barrier film was produced in the same manner as in Example 2, except that the transport speed of the object Z to be treated in a case of forming the base inorganic layer and the silicon nitride layer was set to 0.5 m/min, and in the base inorganic layer forming step, the supply amount of HMDSO was set to 800 sccm, the supply amount of oxygen gas was set to 1200 sccm, and the plasma excitation power was set to 7 kW.

The thickness of the formed base inorganic layer was 740 nm. In addition, the thickness of the formed silicon nitride layer was 20 nm. Therefore, the ratio t₂/t₁ of the thickness t₂ of the base inorganic layer to the thickness t₁ of the silicon nitride layer was 37.

In addition, the thickness of the mixed layer was 4.2 nm.

### Example 13

A gas barrier film was produced in the same manner as in Example 12, except that, in the base inorganic layer forming step, the supply amount of HMDSO was set to 1000 sccm, the supply amount of oxygen gas was set to 1500 sccm, and the plasma excitation power was set to 8 kW.

The thickness of the formed base inorganic layer was 890 nm. Therefore, the ratio t₂/t₁ of the thickness t₂ of the base inorganic layer to the thickness t₁ of the silicon nitride layer was 44.5.

In addition, the thickness of the mixed layer was 4.2 nm.

### Example 14

A gas barrier film was produced in the same manner as in Example 1, except that, in the base inorganic layer forming step, the supply amount of HMDSO was set to 400 sccm, the supply amount of oxygen gas was set to 400 sccm, and the plasma excitation power was set to 4 kW.

The thickness of the formed base inorganic layer was 75 nm. In addition, the thickness of the formed silicon nitride layer was 6 nm. Therefore, the ratio t₂/t₁ of the thickness t₂ of the base inorganic layer to the thickness t₁ of the silicon nitride layer was 12.5.

In addition, the thickness of the mixed layer was 13.9 nm.

In addition, the refractive index of the base inorganic layer was 1.40. Therefore, the difference in refractive index between the base inorganic layer and the silicon nitride layer was 0.4.

### Example 15

A gas barrier film was produced in the same manner as in Example 14, except that the bias power applied to the drum was set to 1.5 kW.

The thickness of the formed base inorganic layer was 72 nm. In addition, the thickness of the formed silicon nitride layer was 4 nm. Therefore, the ratio t₂/t₁ of the thickness t₂ of the base inorganic layer to the thickness t₁ of the silicon nitride layer was 18.

In addition, the thickness of the mixed layer was 16.1 nm.

### Example 16

A gas barrier film was produced in the same manner as in Example 1, except that, after the silicon nitride layer forming step, the following oxygen plasma treatment was performed. In Example 16, among three film forming sections in the film forming apparatus as shown in FIG. 6, a base inorganic layer was formed in the first film forming section, a silicon nitride layer was formed in the second film forming section, and the oxygen plasma treatment was performed in the third film forming section.

(Oxygen Plasma Treatment)

In the film forming section on the downstream side of the film forming section for forming the silicon nitride layer, the object Z to be treated (silicon nitride layer) was subjected to an oxygen plasma treatment. The oxygen plasma treatment causes an increase in content of oxygen element in the silicon nitride layer, which lowers the density and lowers the refractive index.

As a treatment gas, oxygen gas (O₂) was used. The gas supply amount was 600 sccm for oxygen gas. In addition, the film forming pressure was set to 100 Pa. The plasma excitation power was set to 4 kW at a frequency of 13.56 MHz.

The thickness of the formed silicon nitride layer was 9 nm. Therefore, the ratio t₂/t₁ of the thickness t₂ of the base inorganic layer to the thickness t₁ of the silicon nitride layer was 8.9.

In addition, the thickness of the mixed layer was 5.5 nm.

In addition, the refractive index of the silicon nitride layer was 1.7. Therefore, the difference in refractive index between the silicon nitride layer and the base inorganic layer was 0.22.

### Example 17

A gas barrier film was produced in the same manner as in Example 1, except that, after the base inorganic layer forming step and before the silicon nitride layer forming step, the following oxygen plasma treatment was performed. In Example 17, among three film forming sections in the film forming apparatus as shown in FIG. 6, a base inorganic layer was formed in the first film forming section, the oxygen plasma treatment was performed in the second film forming section, and a silicon nitride layer was formed in the third film forming section.

(Oxygen Plasma Treatment)

In the film forming section between the film forming section for forming the base inorganic layer and the film forming section forming the silicon nitride layer, the object Z to be treated (base inorganic layer) was subjected to an oxygen plasma treatment. The oxygen plasma treatment causes an increase in content of oxygen element in the base inorganic layer (silicon oxide film), which increases the density and increases the refractive index.

As a treatment gas, oxygen gas (O₂) was used. The gas supply amount was 600 sccm for oxygen gas. In addition, the film forming pressure was set to 100 Pa. The plasma excitation power was set to 4 kW at a frequency of 13.56 MHz.

The thickness of the mixed layer was 4.6 nm.

In addition, the refractive index of the base inorganic layer was 1.62. Therefore, the difference in refractive index between the silicon nitride layer and the base inorganic layer was 0.18.

### Example 18

A gas barrier film was produced in the same manner as in Example 1, except that, after the silicon nitride layer forming step, the following inorganic protective layer forming step was performed.

In Example 18, among three film forming sections in the film forming apparatus as shown in FIG. 6, a base inorganic layer was formed in the first film forming section, a silicon nitride layer was formed in the second film forming section, and an inorganic protective layer was formed in the third film forming section.

(Inorganic Protective Layer Forming Step)

As a raw material gas for forming the inorganic protective layer, hexamethyldisiloxane (HMDSO) gas and oxygen gas (O₂) were used. The gas supply amount was 400 sccm for HMDSO and 600 sccm for oxygen gas. In addition, the film forming pressure was set to 100 Pa. The plasma excitation power was set to 4 kW at a frequency of 13.56 MHz. That is, the inorganic protective layer is a silicon oxide film.

The thickness of the formed inorganic protective layer was 80 nm.

In addition, the refractive index of the inorganic protective layer was 1.48.

### Example 19

A gas barrier film was produced in the same manner as in Example 1, except that, after forming the base inorganic layer and the silicon nitride layer, the base inorganic layer and the silicon nitride layer were formed again. The conditions for forming the base inorganic layer and the silicon nitride layer for the second time were the same as those for the first time.

That is, the gas barrier film to be produced is a gas barrier film having, as shown in FIG. 5, a substrate 12, a base inorganic layer 14a, a silicon nitride layer 16, a base inorganic layer 14b, and a silicon nitride layer 16 in this order.

The thickness of a mixed layer between the base inorganic layer 14a and the silicon nitride layer 16 was 5.3 nm. In addition, the thickness of a mixed layer between the base inorganic layer 14b and the silicon nitride layer 16 was 5.3 nm.

### Comparative Example 1

A silicon oxide layer was formed on a substrate by using a general RtoR sputtering apparatus, and subsequently, a silicon nitride layer was formed on a silicon oxide layer by using a general sputtering apparatus to produce a gas barrier film. The transport speed of the object to be treated was set to 0.1 m/min.

As an atmosphere gas in a case of forming the silicon oxide layer, water vapor (H₂O), oxygen gas (O₂), and argon gas (Ar) were used. The gas supply amount was 10 sccm for water vapor, 50 sccm for oxygen gas, and 200 sccm for argon gas. In addition, the film forming pressure was set to 0.1 Pa. The target was silicon (Si). The plasma excitation power was set to 1 kW at a frequency of 13.56 MHz.

As an atmosphere gas in a case of forming the silicon nitride layer, nitrogen gas (N₂) and argon gas (Ar) were used. The gas supply amount was 50 sccm for nitrogen gas and 200 sccm for argon gas. In addition, the film forming pressure was set to 0.1 Pa. The target was silicon (Si). The plasma excitation power was set to 1 kW at a frequency of 13.56 MHz.

The thickness of the formed silicon oxide layer (base inorganic layer) was 80 nm. In addition, the thickness of the formed silicon nitride layer was 10 nm. Therefore, the ratio t₂/t₁ of the thickness t₂ of the base inorganic layer to the thickness t₁ of the silicon nitride layer was 8.

In addition, a mixed layer having a thickness of 0.7 nm was detected, but the mixed layer was detected due to the presence of asperity (irregularity) of nm order at a boundary surface of the silicon oxide layer and the silicon nitride layer. Actually, a mixed layer containing a component derived from the base inorganic layer and a component derived from the silicon nitride layer was not formed.

In addition, the refractive index of the silicon oxide layer was 1.48. The refractive index of the silicon nitride layer was 2.0. Therefore, the difference in refractive index between the silicon nitride layer and the base inorganic layer was 0.52.

### Comparative Example 2

A gas barrier film was produced in the same manner as in Example 1, except that the bias power applied to the drum was set to 0 kW.

The thickness of the formed silicon nitride layer was 15 nm. Therefore, the ratio t₂/t₁ of the thickness t₂ of the base inorganic layer to the thickness t₁ of the silicon nitride layer was 5.3.

In addition, the thickness of the mixed layer was 2.5 nm.

<Evaluation>

Gas barrier property (water vapor transmission rate (WVTR)), transparency (total light transmittance), and bending resistance of the produced gas barrier films of Examples and Comparative Examples were evaluated.

(Gas Barrier Property)

Gas barrier property was evaluated by measuring a water vapor transmission rate (WVTR) [g/(m²·day)] according to a calcium corrosion method (method described in JP2005-283561A).

(Transparency)

Transparency was evaluated by measuring total light transmittance using NDH5000 manufactured by NIPPON DENSHOKU INDUSTRIES Co., LTD. in accordance with JIS K 7361-1 (1997).

In a case where the total light transmittance of only the substrate was measured, the total light transmittance of only the substrate was 90%.

(Bending Resistance)

The bending resistance was evaluated by measuring a water vapor transmission rate (WVTR) [g/(m²·day)] after bending the gas barrier film outward at φ8 mm 100000 times, and the evaluation was based on a ratio (WVTR after bending/WVTR before bending) with the water vapor transmission rate before bending. As the value is smaller, bending resistance is higher.

Film forming conditions in each of Examples and Comparative Examples are shown in Table 1, the configurations of the produced gas barrier films are shown in Table 2, and the evaluation results are shown in Table 3.

TABLE 1

| | | | Base inorganic layer forming step | | | | | |
|---|---|---|---|---|---|---|---|---|
| | Transport | | | Gas flow rate | | | | Silicon nitride |
| | speed | Bias | | HMDSO | O₂ | Excitation | Plasma | layer forming step |
| | m/min | power kW | Method | sccm | sccm | power kW | treatment | Method |
| Example 1 | 2 | 1 | CVD | 400 | 600 | 4 | — | CVD |
| Example 2 | 2 | 1 | CVD | 400 | 600 | 4 | — | CVD |
| Example 3 | 1 | 1 | CVD | 400 | 600 | 4 | — | CVD |
| Example 4 | 2 | 0.5 | CVD | 400 | 600 | 4 | — | CVD |
| Example 5 | 1 | 1 | CVD | 600 | 900 | 5.5 | — | CVD |
| Example 6 | 1 | 1 | CVD | 1000 | 1500 | 8 | — | CVD |
| Example 7 | 1 | 1 | CVD | 1200 | 1800 | 10 | — | CVD |
| Example 8 | 2 | 1 | CVD | 150 | 375 | 2 | — | CVD |
| Example 9 | 2 | 1 | CVD | 60 | 90 | 0.5 | — | CVD |
| Example 10 | 0.5 | 1 | CVD | 400 | 600 | 4 | — | CVD |
| Example 11 | 0.5 | 1 | CVD | 400 | 600 | 4 | — | CVD |
| Example 12 | 0.5 | 1 | CVD | 800 | 1200 | 7 | — | CVD |
| Example 13 | 0.5 | 1 | CVD | 1000 | 1500 | 8 | — | CVD |
| Example 14 | 2 | 1 | CVD | 400 | 400 | 4 | — | CVD |
| Example 15 | 2 | 1.5 | CVD | 400 | 400 | 4 | — | CVD |
| Example 16 | 2 | 1 | CVD | 400 | 600 | 4 | — | CVD |
| Example 17 | 2 | 1 | CVD | 400 | 600 | 4 | Y | CVD |
| Example 18 | 2 | 1 | CVD | 400 | 600 | 4 | — | CVD |
| Example 19 | 2 | 1 | CVD | 400 | 600 | 4 | — | CVD |
| | | | CVD | 400 | 600 | 4 | — | CVD |
| Comparative | 0.1 | | Sputtering | 10 | 50 | 1 | — | Sputtering |
| Example 1 | | | | | | | | |
| Comparative | 2 | 0 | CVD | 400 | 600 | 4 | — | CVD |
| Example 2 | | | | | | | | |

| | Silicon nitride layer forming step | | | | | Protective layer forming step | | |
|---|---|---|---|---|---|---|---|---|
| | Gas flow rate | | | | | Gas flow rate | | |
| | SiH₄ | NH₃ | H₂ | Excitation | Plasma | HMDSO | O₂ | Excitation |
| | sccm | sccm | sccm | power kW | treatment | sccm | sccm | power kW |
| Example 1 | 200 | 600 | 1000 | 1.5 | — | — | — | — |
| Example 2 | 100 | 300 | 1000 | 0.8 | — | — | — | — |
| Example 3 | 100 | 300 | 1000 | 0.8 | — | — | — | — |
| Example 4 | 200 | 600 | 1000 | 1.5 | — | — | — | — |
| Example 5 | 100 | 300 | 1000 | 0.8 | — | — | — | — |
| Example 6 | 100 | 300 | 1000 | 0.8 | — | — | — | — |
| Example 7 | 100 | 300 | 1000 | 0.8 | — | — | — | — |
| Example 8 | 200 | 600 | 1000 | 1.5 | — | — | — | — |
| Example 9 | 200 | 600 | 1000 | 1.5 | — | — | — | — |
| Example 10 | 400 | 1200 | 2000 | 3.5 | — | — | — | — |
| Example 11 | 500 | 1500 | 2000 | 4.5 | — | — | — | — |
| Example 12 | 100 | 300 | 1000 | 0.8 | — | — | — | — |
| Example 13 | 100 | 300 | 1000 | 0.8 | — | — | — | — |
| Example 14 | 200 | 600 | 1000 | 1.5 | — | — | — | — |
| Example 15 | 200 | 600 | 1000 | 1.5 | — | — | — | — |
| Example 16 | 200 | 600 | 1000 | 1.5 | Y | — | — | — |
| Example 17 | 200 | 600 | 1000 | 1.5 | — | — | — | — |
| Example 18 | 200 | 600 | 1000 | 1.5 | — | 400 | 600 | 4 |
| Example 19 | 200 | 600 | 1000 | 1.5 | — | — | — | — |
| | 200 | 600 | 1000 | 1.5 | — | | | |
| Comparative | 50 | 200 | | 1 | — | — | — | — |
| Example 1 | | | | | | | | |
| Comparative | 200 | 600 | 1000 | 1.5 | — | — | — | — |
| Example 2 | | | | | | | | |

TABLE 2

| | Base inorganic layer | | | Silicon nitride layer | | | Pro- | Mixed layer | | Difference in |
|---|---|---|---|---|---|---|---|---|---|---|
| | Compo- | Thickness | Refractive | Compo- | Thickness | Refractive | tective | Thickness | Thickness | refractive |
| | sition | t₂ nm | index | sition | t₁ nm | index | layer | nm | ratio t₂/t₁ | index |
| Example 1 | SiO | 80 | 1.48 | SiN | 10 | 1.8 | — | 5.3 | 8 | 0.32 |
| Example 2 | SiO | 80 | 1.48 | SiN | 5 | 1.8 | — | 4.5 | 16 | 0.32 |
| Example 3 | SiO | 170 | 1.48 | SiN | 10 | 1.8 | — | 4.7 | 17 | 0.32 |
| Example 4 | SiO | 80 | 1.48 | SiN | 12 | 1.8 | — | 3.2 | 6.7 | 0.32 |
| Example 5 | SiO | 240 | 1.48 | SiN | 10 | 1.8 | — | 5 | 24 | 0.32 |
| Example 6 | SiO | 450 | 1.48 | SiN | 10 | 1.8 | — | 5.1 | 45 | 0.32 |
| Example 7 | SiO | 570 | 1.48 | SiN | 10 | 1.8 | — | 5.1 | 57 | 0.32 |
| Example 8 | SiO | 32 | 1.48 | SiN | 10 | 1.8 | — | 5.3 | 3.2 | 0.32 |
| Example 9 | SiO | 15 | 1.48 | SiN | 10 | 1.8 | — | 5.3 | 1.5 | 0.32 |
| Example 10 | SiO | 350 | 1.48 | SiN | 92 | 1.8 | — | 6.2 | 3.8 | 0.32 |
| Example 11 | SiO | 350 | 1.48 | SiN | 106 | 1.8 | — | 6.4 | 3.3 | 0.32 |
| Example 12 | SiO | 740 | 1.48 | SiN | 20 | 1.8 | — | 4.2 | 37 | 0.32 |
| Example 13 | SiO | 890 | 1.48 | SiN | 20 | 1.8 | — | 4.2 | 44.5 | 0.32 |
| Example 14 | SiO | 75 | 1.4 | SiN | 6 | 1.8 | — | 13.9 | 12.5 | 0.4 |
| Example 15 | SiO | 72 | 1.4 | SiN | 4 | 1.8 | — | 16.1 | 18 | 0.4 |
| Example 16 | SiO | 80 | 1.48 | SiN | 9 | 1.7 | — | 5.5 | 8.9 | 0.22 |
| Example 17 | SiO | 80 | 1.62 | SiN | 10 | 1.8 | — | 4.6 | 8 | 0.18 |
| Example 18 | SiO | 80 | 1.48 | SiN | 10 | 1.8 | SiO | 5.4 | 8 | 0.32 |
| Example 19 | SiO | 80 | 1.48 | SiN | 10 | 1.8 | — | 5.3 | 8 | 0.32 |
| | SiO | 80 | 1.48 | SiN | 10 | 1.8 | | 5.3 | | |
| Comparative | SiO | 80 | 1.48 | SiN | 10 | 2 | — | 0.7 | 8 | 0.52 |
| Example 1 | | | | | | | | | | |
| Comparative | SiO | 80 | 1.48 | SiN | 15 | 1.8 | — | 2.5 | 5.3 | 0.32 |
| Example 2 | | | | | | | | | | |

TABLE 3

| | Evaluation | | |
|---|---|---|---|
| | Gas barrier | | |
| | property | | Transparency |
| | WVTR | Bending | Total light |
| | g/(m² · day) | resistance | transmittance % |
| Example 1 | 4.00E−05 | 1.1 | 88 |
| Example 2 | 5.00E−05 | 1.1 | 89 |
| Example 3 | 3.00E−05 | 1.2 | 88 |
| Example 4 | 4.00E−05 | 1.2 | 86 |
| Example 5 | 3.00E−05 | 1.2 | 88 |
| Example 6 | 3.00E−05 | 2.7 | 86 |
| Example 7 | 4.00E−05 | 5.3 | 84 |
| Example 8 | 7.00E−05 | 1.2 | 87 |
| Example 9 | 2.00E−04 | 1.1 | 87 |
| Example 10 | 2.00E−05 | 3.6 | 86 |
| Example 11 | 2.00E−05 | 6.9 | 83 |
| Example 12 | 3.00E−05 | 4.4 | 86 |
| Example 13 | 2.00E−05 | 7 | 85 |
| Example 14 | 6.00E−05 | 1.3 | 87 |
| Example 15 | 1.00E−04 | 1.3 | 87 |
| Example 16 | 7.00E−05 | 1.1 | 86 |
| Example 17 | 4.00E−05 | 4.1 | 83 |
| Example 18 | 2.00E−05 | 1.2 | 87 |
| Example 19 | 6.00E−06 | 3.1 | 87 |
| Comparative | 0.06 | 100 | 83 |
| Example 1 | | | |
| Comparative | 3.00E−05 | 10.2 | 84 |
| Example 2 | | | |

As shown in Tables 1 to 3, compared with Comparative Examples, it is found that the gas barrier film according to the embodiment of the present invention, which has the base inorganic layer formed of silicon oxide, the silicon nitride layer, and a mixed layer between the base inorganic layer and the silicon nitride layer, in which the mixed layer has a thickness of 3 nm or more, has excellent bending resistance.

In contrast, it is found that Comparative Example 1 not having the mixed layer and Comparative Example 2 having a thin mixed layer have poor bending resistance. In addition, it is found that, in Comparative Example 1 in which the silicon nitride layer is formed by sputtering, the silicon nitride layer does not exhibit gas barrier property so that gas barrier property is poor.

From the comparison of Examples 1, 2, 10, and 11, it is found that, mainly from the viewpoint of bending resistance, the thickness of the silicon nitride layer is preferably 100 nm or less and more preferably 50 nm or less.

From the comparison of Examples 1, 3, 12, and 13, it is found that, mainly from the viewpoint of bending resistance, the thickness of the base inorganic layer is preferably 800 nm or less.

From the comparison of Examples 1, 4, 14, and 15, it is found that, mainly from the viewpoint of gas barrier property, the thickness of the mixed layer is preferably 15 nm or less.

From the comparison of Examples 1 and 5 to 9, it is found that, from the viewpoint of bending resistance and gas barrier property, the ratio t₂/t₁ of the thickness t₂ of the base inorganic layer 14 to the thickness t₁ of the silicon nitride layer 16 is preferably 2 to 50.

From the comparison of Examples 1, 16, and 17 and Comparative Example 1, it is found that, from the viewpoint of transparency, the difference in refractive index is preferably 0.2 or more and 0.5 or less.

From the comparison between Examples 1 and 18, from the viewpoint of gas barrier property, it is found that it is preferable to have a protective layer.

From the comparison between Example 1 and Example 19, it is found that, by having two or more combinations of the base inorganic layer and the silicon nitride layer, gas barrier property is further enhanced.

From the above results, the effect of the present invention is clear.

The present invention can be suitably used as a sealing material for organic EL elements, solar cells, and the like.

### EXPLANATION OF REFERENCES

10, 10a to 10c: gas barrier film
12: substrate
14, 14a and 14b: base inorganic layer
15: mixed layer
16: silicon nitride layer
18: protective layer
36: laminate roll
50: film forming apparatus
52: vacuum chamber
52a: inner wall surface
54: unwinding section
56a to 56d: partition wall
58, 76, 86, 96: vacuum exhaust unit
60: drum
62: rotating shaft
63a and 63b: guide roller
64: winding shaft
68: bias power supply
70, 80, 90: film forming electrode
72, 82, 92: high-frequency power supply
74, 84, 94: raw material gas supply unit
78: first film forming section
88: second film forming section
98: third film forming section
Z: object to be treated

What is claimed is:

1. A gas barrier film comprising:
a substrate;
a base inorganic layer;
a silicon nitride layer formed using the base inorganic layer as a base; and
a mixed layer formed at a boundary surface of the base inorganic layer and the silicon nitride layer,
wherein the base inorganic layer contains silicon oxide,
the mixed layer contains a component derived from the base inorganic layer and a component derived from the silicon nitride layer, and
a thickness of the mixed layer is 3 nm or more.

2. The gas barrier film according to claim 1,
wherein a ratio t₂/t₁ of a thickness t₂ of the base inorganic layer to a thickness t₁ of the silicon nitride layer is 2 to 50.

3. The gas barrier film according to claim 1,
wherein a refractive index of the silicon nitride layer is higher than a refractive index of the base inorganic layer.

4. The gas barrier film according to claim 1,
wherein a difference between a refractive index of the silicon nitride layer and a refractive index of the base inorganic layer is 0.2 to 0.5.

5. The gas barrier film according to claim 1,
wherein the thickness of the mixed layer is 3 nm to 15 nm.

6. The gas barrier film according to claim 2,
wherein the thickness of the mixed layer is 3 nm to 15 nm.

7. The gas barrier film according to claim 1,
wherein a thickness of the base inorganic layer is 5 nm to 800 nm.

8. The gas barrier film according to claim 2,
wherein the thickness of the base inorganic layer is 5 nm to 800 nm.

9. The gas barrier film according to claim 1,
wherein a thickness of the silicon nitride layer is 3 nm to 100 nm.

10. The gas barrier film according to claim 2,
wherein the thickness of the silicon nitride layer is 3 nm to 100 nm.

11. The gas barrier film according to claim 1,
wherein a refractive index of the silicon nitride layer is higher than a refractive index of the base inorganic layer,
the thickness of the mixed layer is 3 nm to 15 nm,
a thickness of the base inorganic layer is 5 nm to 800 nm, and
a thickness of the silicon nitride layer is 3 nm to 100 nm.

12. The gas barrier film according to claim 1,
wherein a refractive index of the silicon nitride layer is 1.7 to 2.2.

13. The gas barrier film according to claim 1,
wherein a refractive index of the base inorganic layer is 1.3 to 1.6.

14. The gas barrier film according to claim 1,
wherein two or more combinations of the silicon nitride layer and the base inorganic layer are provided.

15. The gas barrier film according to claim 1,
wherein
a ratio t₂/t₁ of a thickness t₂ of the base inorganic layer to a thickness t₁ of the silicon nitride layer is 2 to 50,
a refractive index of the silicon nitride layer is higher than a refractive index of the base inorganic layer,
a difference between the refractive index of the silicon nitride layer and the refractive index of the base inorganic layer is 0.2 to 0.5,
the thickness of the mixed layer is 3 nm to 15 nm,
a thickness of the base inorganic layer is 5 nm to 800 nm,
a thickness of the silicon nitride layer is 3 nm to 100 nm,
the refractive index of the silicon nitride layer is 1.7 to 2.2,
the refractive index of the base inorganic layer is 1.3 to 1.6, and
two or more combinations of the silicon nitride layer and the base inorganic layer are provided.
